(19) United States
(12) Patent Application Publication
(10) Pub. No.: US 2020/0066748 A1
(43) Pub. Date: Feb. 27, 2020

(54) SEMICONDUCTOR MEMORY DEVICE

(71) Applicant: Toshiba Memory Corporation, Minato-ku (JP)

(72) Inventors: Daisuke MATSUSHITA, Yokkaichi (JP); Yui KAGI, Yokkaichi (JP); Tatsuya FUJISHIMA, Yokkaichi (JP); Masayuki SHISHIDO, Yokkaichi (JP); Nozomi KIDO, Yokkaichi (JP); Tomonori KAJINO, Yokkaichi (JP); Nobuhito KUGE, Yokkaichi (JP)

(73) Assignee: Toshiba Memory Corporation, Minato-ku (JP)

(21) Appl. No.: 16/208,673

(22) Filed: Dec. 4, 2018

(30) Foreign Application Priority Data
Aug. 27, 2018 (JP) 2018-158694

(51) Int. Cl. H01L 27/11582; H01L 29/10; H01L 29/04; H01L 27/11519; H01L 27/11556; H01L 27/11565; H01L 29/788; H01L 29/792; H01L 29/16; G11C 16/04; G11C 16/10; H01L 21/02; H01L 21/28

(52) U.S. Cl. CPC H01L 27/11582; H01L 21/02667; H01L 29/04; H01L 27/11519; H01L 27/11556; H01L 27/11565; H01L 29/7883; H01L 29/7889; H01L 29/7926; H01L 29/16; G11C 16/0483; G11C 16/10; H01L 21/0217; H01L 21/28282; H01L 21/28273; H01L 21/02532; H01L 21/02592; H01L 29/1037

(57) ABSTRACT

According to one embodiment, a semiconductor memory device includes a stacked body in which a plurality of insulating layers and a plurality of conductive layers are alternately stacked above a substrate, a pillar that penetrates the stacked body while extending in a stacking direction of the stacked body, and a semiconductor layer, a first insulating layer, a charge accumulation layer, and a second insulating layer, which are stacked on a side surface of the pillar in order from the pillar, wherein the semiconductor layer has an average grain size that is larger on a side nearer to the pillar and is smaller on a side nearer to the first insulating layer.

### CROSS-REFERENCE TO RELATED APPLICATIONS

This application is based upon and claims the benefit of priority front Japanese Patent Application No. 2018-158694, filed on Aug. 27, 2018; the entire content of which are incorporated herein by reference.

### FIELD

An embodiment of the present invention relates generally to a semiconductor memory device.

### BACKGROUND

In a three-dimensional nonvolatile memory, there are pillars extending in the height direction, and a plurality of memory cells are arrayed in the height direction of each of the pillars, such that the memory cells share a channel layer on the side surface of each pillar. In the three-dimensional nonvolatile memory, it is desired to improve the writing characteristic.

### BRIEF DESCRIPTION OF THE DRAWINGS

FIG. 1 shows a sectional view along a certain one of the conductive layers of a semiconductor memory device according to an embodiment, and an enlarged view near a columnar structure;

FIG. 2 is a sectional view illustrating the semiconductor memory device according to the embodiment in the stacking direction, which is taken along a line A-A′ of FIG. 1;

FIG. 3 is a flow-related diagram illustrating an example of a procedure in a manufacturing process for the semiconductor memory device according to the embodiment;

FIG. 4 is a flow-related diagram illustrating an example of a procedure in the manufacturing process for the semiconductor memory device according to the embodiment;

FIG. 5 is a flow-related diagram illustrating an example of a procedure in the manufacturing process for semiconductor memory device according to the embodiment;

FIG. 6 is a flow-related diagram illustrating an example of a procedure in the manufacturing process for the semiconductor memory device according to the embodiment;

FIG. 7 is a flow-related diagram illustrating an example of a procedure in the manufacturing process for the semiconductor memory device according to the embodiment;

FIG. 8 is a flow-related diagram illustrating an example of a procedure in the manufacturing process for the semiconductor memory device according to the embodiment;

FIG. 9 is a flow-related diagram illustrating an example of a procedure in the manufacturing process for the semiconductor memory device according to the embodiment;

FIG. 10 is a flow-related diagram illustrating an example of a procedure in the manufacturing process for the semiconductor memory device according to the embodiment; and

FIG. 11 is a flow-related diagram illustrating an example of a procedure in the manufacturing process for the semiconductor memory device according to the embodiment.

### DETAILED DESCRIPTION

In general, according to one embodiment, a semiconductor memory device includes a stacked body in which a plurality of insulating layers and a plurality of conductive layers are alternately stacked above a substrate, a pillar that penetrates the stacked body while extending in a stacking direction of the stacked body, and a semiconductor layer, a first insulating layer, a charge accumulation layer, and a second insulating layer, which are stacked on a side surface of the pillar in order from the pillar, wherein the semiconductor layer has an average grain size that is larger on a side nearer to the pillar and is smaller on a side nearer to the first insulating layer.

The present invention will be explained below detail with reference to the accompanying drawings. The present invention is not limited to the following embodiment. The constituent elements in the following embodiment encompass those which can be easily assumed by a person skilled in the art, or which are substantially equivalent thereto.

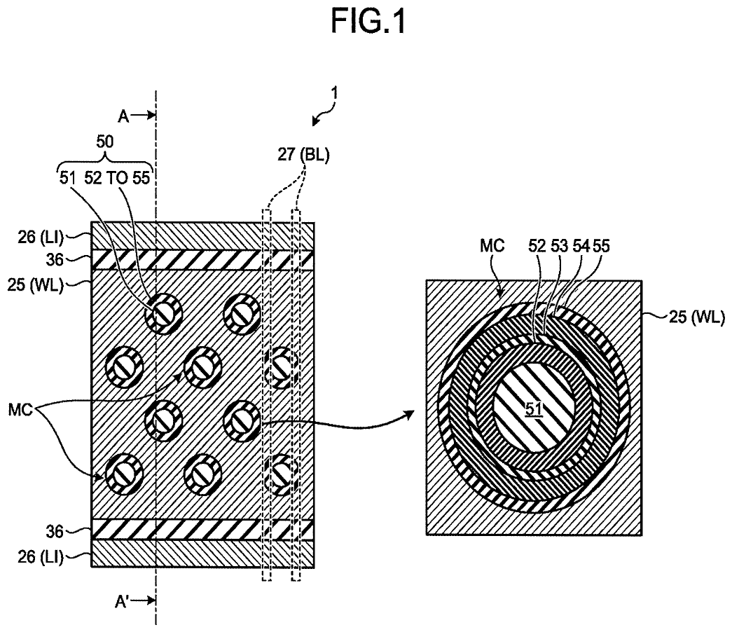

Next, an explanation will be given of a semiconductor memory device according to an embodiment, with reference to FIGS. 1 to 11.

[Configuration Example of Semiconductor Memory Device]

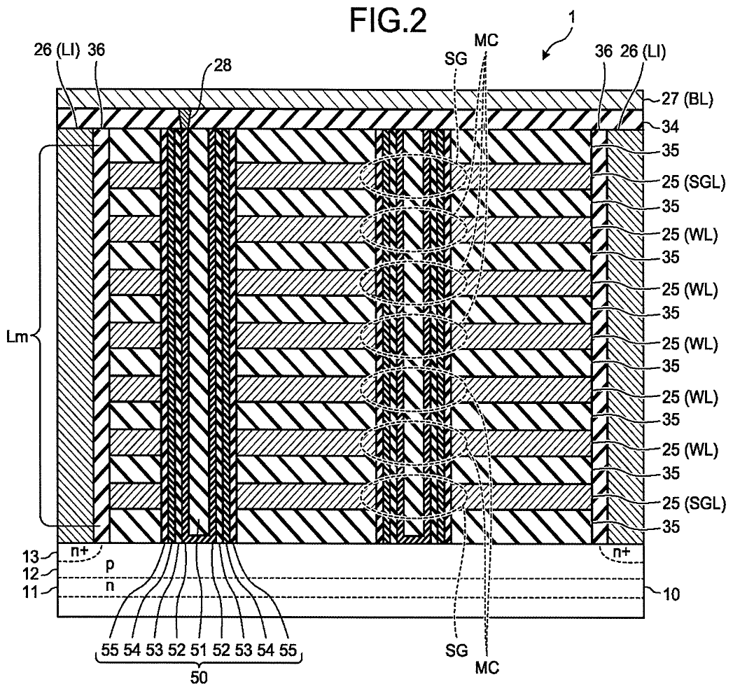

FIG. 1 shows a sectional view along a certain one of the conductive layers 25 of a semiconductor memory device 1 according to an embodiment, and an enlarged view near a columnar structure 50. In FIG. 1, it should be noted that only two bit lines BL are illustrated. FIG. 2 is a sectional view illustrating the semiconductor memory device 1 according to the embodiment in the stacking direction, which is taken along a line A-A′ of FIG. 1.

As illustrated in FIGS. 1 and 2, the semiconductor memory device 1 according to the embodiment is formed as a NAND type flash memory that has, for example, a three-dimensional structure on a semiconductor substrate 10, such as a silicon substrate. The semiconductor substrate 10 includes an n-well 11 in a surface layer part, and further includes a p-well 12 in the n-well 11, and a plurality of n⁺-wells 13 in the p-well 12. Here, the semiconductor memory device 1 may be formed on a conductive layer functioning as a source line, instead of being formed directly on the substrate, such as the semiconductor substrate 10.

On the semiconductor substrate 10, a stacked body Lm is formed, in which a plurality of conductive layers 25 and a plurality of insulating layers 35 are alternately stacked. Each of the conductive layers 25 is, for example, a W layer or the like, and each of the insulating layers 35 is, for example, an SiO₂ layer or the like.

In the stacked body Lm of the conductive layers 25 and the insulating layers 35, there are a plurality of columnar structures 50 formed in a state of penetrating the stacked body Lm. The columnar structures 50 are arranged on the p-well 12, at respective positions between two of the n⁺-wells 13 of the semiconductor substrate 10. Each of the columnar structures 50 is formed, for example, substantially in a circular shape, when seen in a plan view. Here, each columnar structure 50 may be formed, for example, substantially in an elliptical shape, when seen in a plan view.

Each columnar structure 50 includes a core portion 51 serving as a pillar. On the sidewall of the core portion 51, there are a plurality of layers formed in a state of surrounding the sidewall of the core portion 51. These layers are a channel layer 52 serving as a semiconductor layer, a tunnel insulating layer 53 serving as a first insulating layer, a charge accumulation layer 54, and a block insulating layer 55 serving as a second insulating layer, in this order from the core portion 51 side. The core portion 51 is formed of an insulator containing, for example, SiO₂ or the like as the main component. The channel layer 52 is formed of, for example, a silicon layer or the like, the charge accumulation layer 54 is formed of, for example, an SiN layer or the like, and each of the tunnel insulating layer 53 and the block insulating layer 55 is formed of, for example, an SiO₂ layer or the like. Here, the charge accumulation layer 54 may be formed of a floating gate that is conductive and is covered with an insulator around the outside.

The channel layer 52 includes at least two types of silicon layers different in crystal structure. For example, the average grain size of the channel layer 52 is larger the core portion 51 side and is smaller on the tunnel insulating layer 53 side. In other words, the crystallinity of the channel layer 52 is higher on the core portion 51 side and is lower on the tunnel insulating layer 53 side. It can also be said that, in the channel layer 52, the layer on the core portion 51 side is a layer lower in electrical resistivity than the layer on the tunnel insulating layer 53 side. The layer of the channel layer 52 on the core portion 51 side has a layer thickness ratio of, for example, 40% or more and 90% or less, more preferably 50% or more and 80% or less, with respect to the entire channel layer 52. Here, in the channel layer 52, the crystal structure of either of the layer on the core portion 51 side and the layer on the tunnel insulating layer 53 side is not single, as the case may be. Further, there is a case where neither of these layers has a distinct interface. Incidentally, the average grain size and/or crystallinity of the channel layer 52 can be measured by using a nano-beam diffraction method, for example.

More specifically, in the channel layer 52, the layer on the core portion 51 side may contain much single crystal silicon or polysilicon, and the layer on the tunnel insulating layer 53 side may contain much amorphous silicon. Alternatively, in the channel layer 52, the layer on the core portion 51 side may contain much single crystal silicon, and the layer on the tunnel insulating layer 53 side may contain much amorphous silicon or polysilicon.

The semiconductor memory device 1 includes conductive layers 26 outside the stacked body Lm of the conductive layers 25 and the insulating layers 35, at positions on the n⁺-wells 13 of the semiconductor substrate 10. The conductive layers 26 are arranged in a state of sandwiching the stacked body Lm from the opposite sides, with their main surfaces facing the stacked body Lm side. An insulating layer 36 is interposed between each of the conductive layers 26 and the stacked body Lm.

Further, the semiconductor memory device includes conductive layers 27 above the stacked body Lm of the conductive layers 25 and the insulating layers 35, such that the conductive layers 27 extend in a direction almost parallel to the main surface of the semiconductor substrate 10. An insulating layer 34 is interposed between the conductive layers 27 and the stacked body Lm. The channel layer 52 included in each columnar structure 50 is connected to a conductive layer 27 by a contact 28 penetrating the insulating layer 34. More specifically, a predetermined conductive layer 27 of the plurality of conductive layers 27 existing there is connected to the channel layer 52 of a predetermined columnar structure 50.

[Function of Semiconductor Memory Device]

Next, an explanation will be given of a function of the semiconductor memory device 1 serving as a three-dimensional NAND type flash memory, with reference to FIGS. 1 and 2 again.

The channel layer 52, the tunnel insulating layer 53, the charge accumulation layer 54, and the block insulating layer 55, which are included in each columnar structure 50, function as nonvolatile memory cells MC, at least partly. The memory cells MC are arranged at the height positions of the conductive layers 25 that make a stacked structure. Specifically, a plurality of memory cells MC are arrayed on each columnar structure 50 in the height direction of the columnar structure 50. These memory cells MC are electrically connected to each other in series to function as a continuous memory string present on the side surface of one core portion 51.

Of the stacked conductive layers 25, those portions in contact with at least the side surface of each columnar structure 50, together with those portions present nearby, function as word lines WL connected to the memory cells MC. Each of the memory cells MC is arranged in association with the corresponding one of the word lines OIL present at the same height.

Of the plurality of conductive layers 25, those conductive layers 25 at the uppermost layer and the lowermost layer function as selection gate lines SGL. The selection gate lines SGL are used to select a predetermined memory string from the memory strings connected in co to a certain one of the conductive layers 27. Further, those portions of the channel layer 52, the tunnel insulating layer 53, the charge accumulation layer 54, and the block insulating layer 55, which correspond to the selection gate lines SGL, function as selection gates SG. When the selection gates SG are turned on or off, a predetermined memory string is set into a selected state or non-selected state.

Each of the conductive layers 26 present outside these memory cells MC arranged in a matrix format functions as a plate-like source line contact LI, which is connected to the semiconductor substrate 10 functioning as a source line. Further, the conductive layers 27 arranged above the memory cells MC function as bit lines BL.

[Operation of Semiconductor Memory Device]

Next, an explanation will be given of an operation example of the semiconductor memory device 1, with reference to FIGS. 1 and 2 again.

When data “0” (for example, “H” level data (is to be written into a memory cell MC, a write voltage is applied to the word line WL connected to the memory cell MC. Here, the memory cell MC includes the channel layer 52, which is connected to a bit line BL and to the semiconductor substrate 10 serving as a source line. At this time, in the channel layer 52, a channel is formed, in which, for example, the ground potential is supplied and electrons flow. As the channel is formed in the channel layer 52, electrons in the channel pass through the tunnel insulating layer 53 and are injected into and accumulated in the charge accumulation layer 54. Consequently, the threshold voltage with of the memory cell MC is raised, and data “0” is thereby written therein.

At this time, in the channel layer 52, the channel in which electrons flow is formed nearer to the core portion 51 that is lower in electrical resistivity. Accordingly, electrons serving as carriers are unevenly distributed in the channel layer 52 in a state of being nearer to the core portion 51. In this way, as the inside of the channel layer 52 has different crystal structures, the channel layer 52 behaves as a retrograde channel that partly includes a low resistivity layer.

When data “1” (for example, “L” level data) is to be written into a memory cell MC, the channel of the channel layer 52 is set into a floating state so as not to inject electrons into the charge accumulation layer 54, and data “1” is thereby written.

[Manufacturing Process for Semiconductor Memory Device]

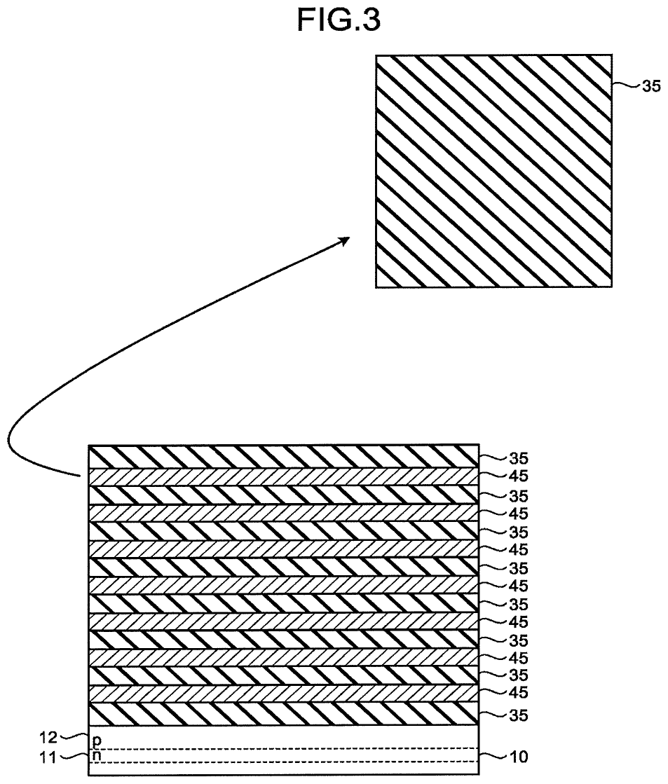

Next, an explanation will be given of a manufacturing process example for the semiconductor memory device 1, with reference to FIGS. 3 to 11. FIGS. 3 to 11 are flow-related diagrams illustrating examples of procedures in a manufacturing process for the semiconductor memory device 1 according to the embodiment. In each of FIGS. 3 to 11, the upper side shows a plan view of the semiconductor memory device 1 in the middle of manufacturing, and the lower side shows a sectional view of the same. Here, in each of FIGS. 3 to 11, the regions corresponding to the source line contacts LI and the insulating layers 36 are omitted.

As illustrated in FIG. 3, on the semiconductor substrate 10 formed with the n-well 11, the p-well 12, the n⁺-wells (not illustrated), and so forth, a stacked structure is formed on the p-well 12 by alternately stacking the insulating layer 35 and a sacrificial layer 45 as a number of layers. The sacrificial layer 45 is an insulating layer made of a material, such as SiN, different from that of the insulating layer 35. The sacrificial layer 45 is a layer to be replaced with the conductive layer 25 later.

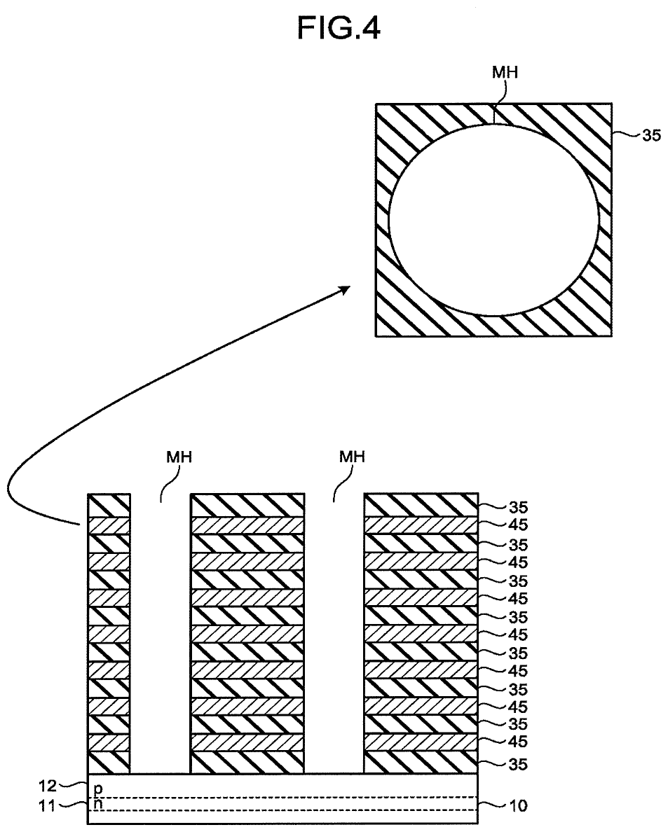

Then, as illustrated in FIG. 4, memory holes MH are formed to penetrate the stacked structure of the sacrificial layers 45 and the insulating layers 35 and to reach the semiconductor substrate 10. Each of the memory holes MH is formed at a region for forming the columnar structure 50.

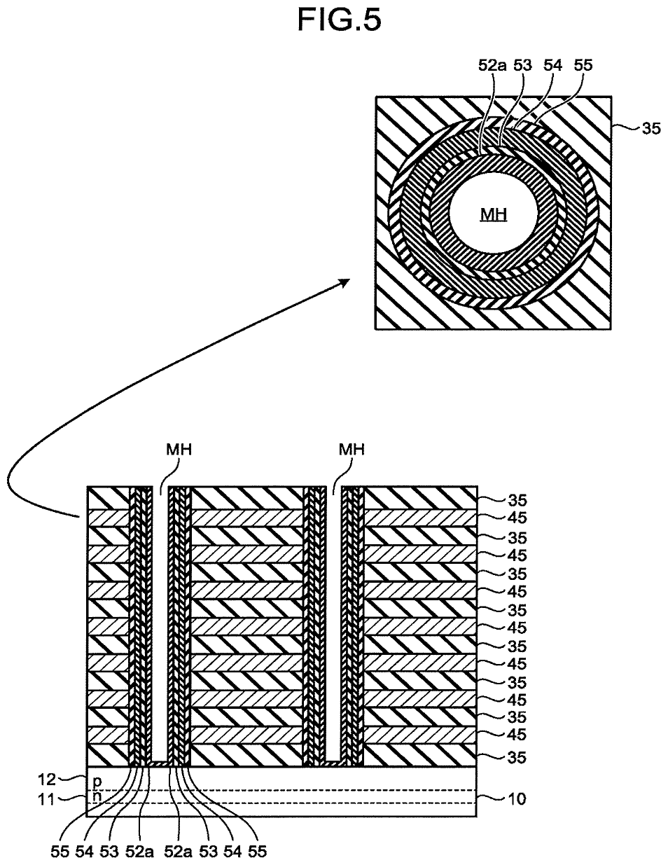

Then, as illustrated in FIG. 5, an insulating material is deposited inside each memory hole PH to form the block insulating layer 55 on the inner wall of the memory hole MH. Further, an insulating material is deposited inside each memory hole MH to form the charge accumulation layer 54 on the block insulating layer 55. Further, an insulating material is deposited inside each memory hole MH to form the tunnel insulating layer 53 on the charge accumulation layer 54. Further, a semiconductor material is deposited inside each memory hole PH to form a channel layer 52a on the tunnel insulating layer 53. At this time, the channel layer 52a does not include layers different in crystal structure, but has been formed entirely as a layer made of, for example, amorphous silicon or the like.

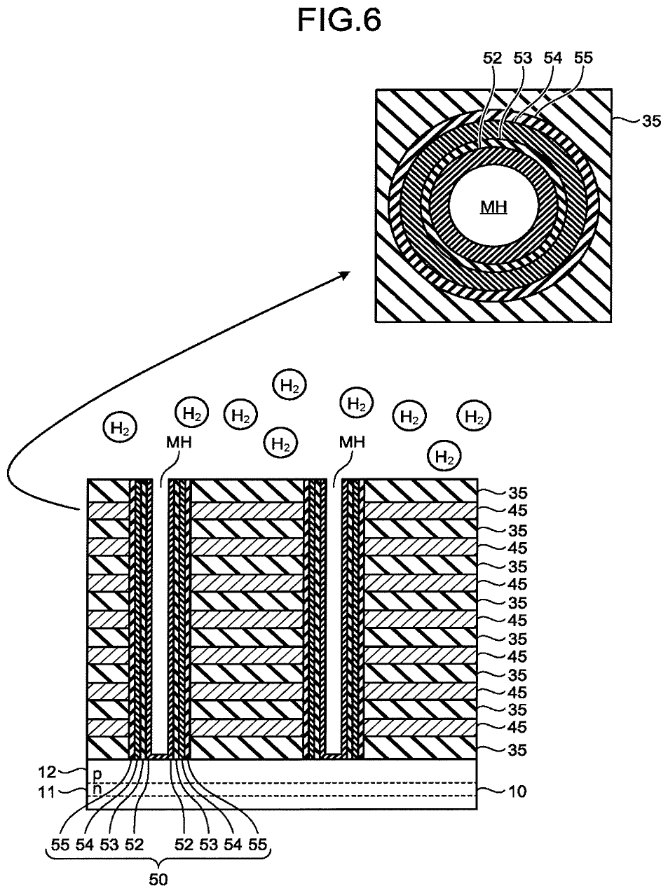

Then, as illustrated in FIG. 6, the entire resultant structure is annealed at a temperature of 1,000° C. or lower in a hydrogen atmosphere. The hydrogen atmosphere is an atmosphere containing at least hydrogen gas, and the atmosphere may contain an inactive gas, such as nitrogen gas or a rare gas.

Consequently, amorphous silicon forming the channel layer 52a is melted, in the surface layer of the channel layer 52a, i.e., in that part of the channel layer 52a, which is down to a predetermined depth in the depth direction from the surface opposite to the tunnel insulating layer 53. The predetermined depth, to which the channel layer 52a is to be melted here, reaches, for example, a depth of 40% or more and 90% or less, more preferably a depth of 50% or more and 80% or less, in the channel layer 52a. Then, silicon atoms in the melted part migrate within the surface layer of the channel layer 52a, and are reconstructed to form a more stable arrangement.

The part thus reconstructed is larger in average grain size and higher in crystallinity, as compared to the other part left unmelted. Accordingly, the reconstructed part contains much single crystal silicon. In this way, the channel layer 52 is formed that includes at least two types of silicon layers different in crystal structure.

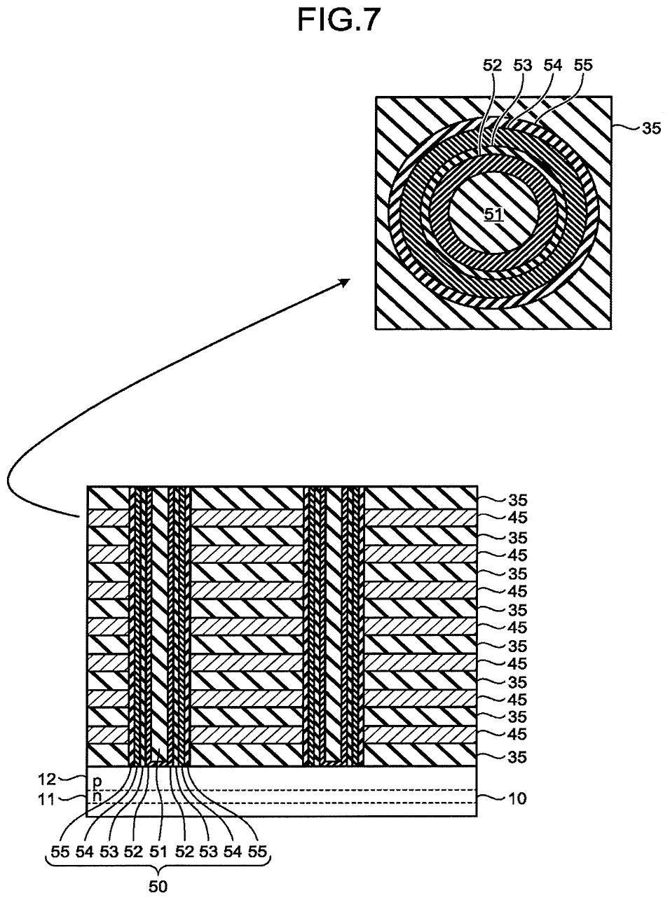

Then, as illustrated in FIG. 7, an insulating material is deposited or applied to fill each memory hole MH almost completely, and thereby to form the core portion 51 in the region surrounded by the channel layer 52. Consequently, the columnar structures 50 are formed.

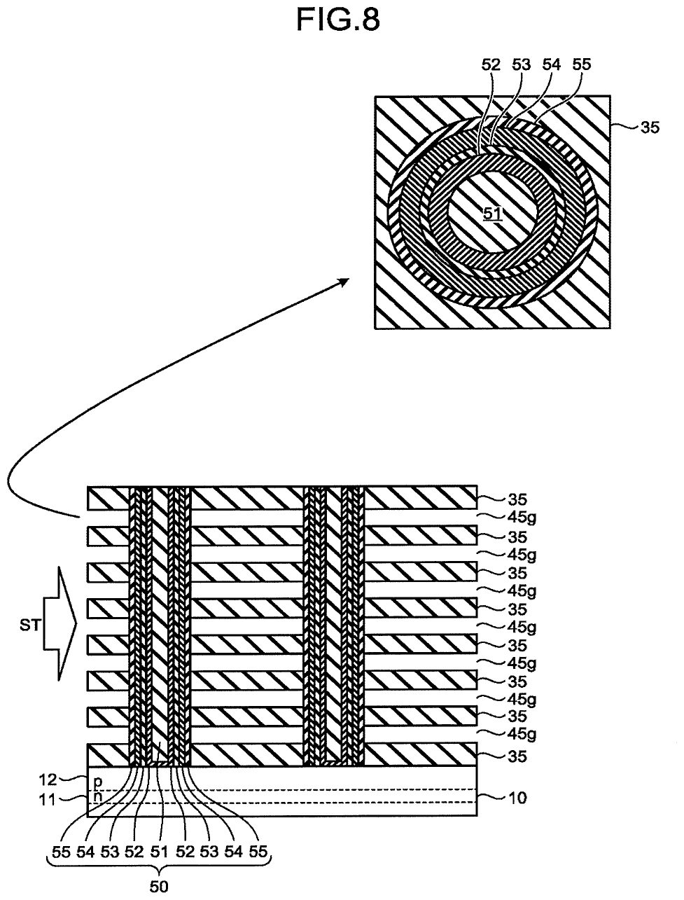

Then, as illustrated in FIG. 8, the sacrificial layers 45 are removed through a slit ST, which has been formed around the region formed with the columnar structures 50 in a state of penetrating the stacked structure of the sacrificial layers 45 and the insulating layers 35. Consequently, gaps 45g are formed between the insulating layers 35, from which the sacrificial layers 45 have been removed.

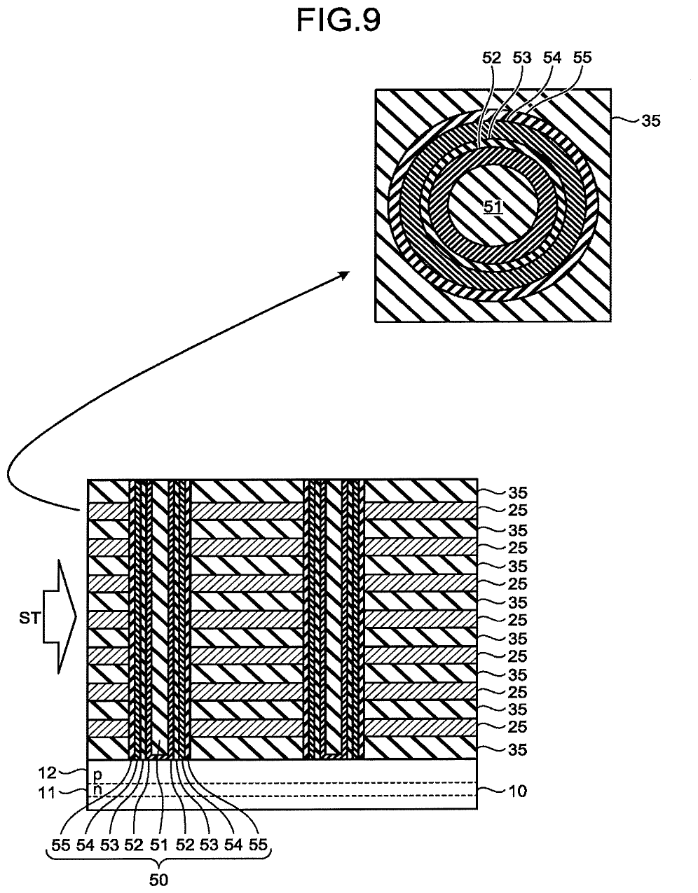

Then, as illustrated in FIG. 9, a conductive material is filled, through the slit ST around the region formed with the columnar structures 50, into the gaps 45g formed by removing the sacrificial layers 45. Consequently, the conductive layers 25 are formed in a state of being alternately stacked between the insulating layers 35.

The procedures illustrated in FIGS. 8 and 9 are sometimes called “replacement” with the conductive layers 25. For this replacement, heat at a temperature of 1,000° C. or higher is applied, in some oases. Consequently, there is a case where the layer of the channel layer 52 which contains much single crystal silicon is partly or entirely denatured to contain much polysilicon. Further, there is a case where the layer of the channel layer 52 which corresponds to the unmelted part and contains much amorphous silicon is partly or entirely denatured to contain much polysilicon.

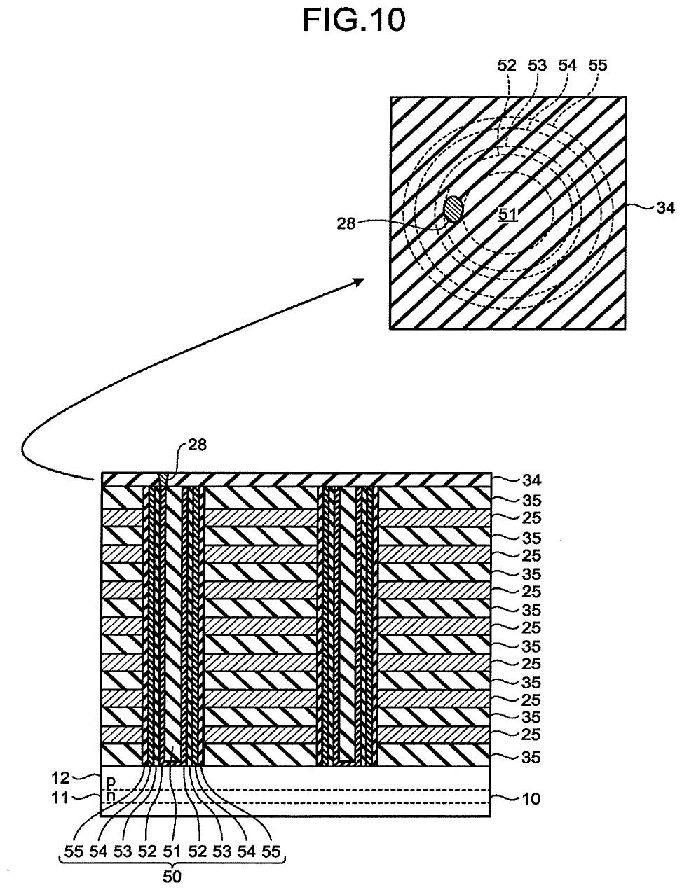

Then, as illustrated in FIG. 10, the insulating layer 34 is formed on the upper surface of the stacked body of the conductive layers 25 and the insulating layers 35. Further, through holes are formed IF the insulating layer 34 such that each of the through holes is at a position overlapping with the channel layer 52 of a predetermined columnar structure 50, when seen in a plan view. Then, a conductive material is embedded into the through holes. Consequently, the contacts 28 are formed.

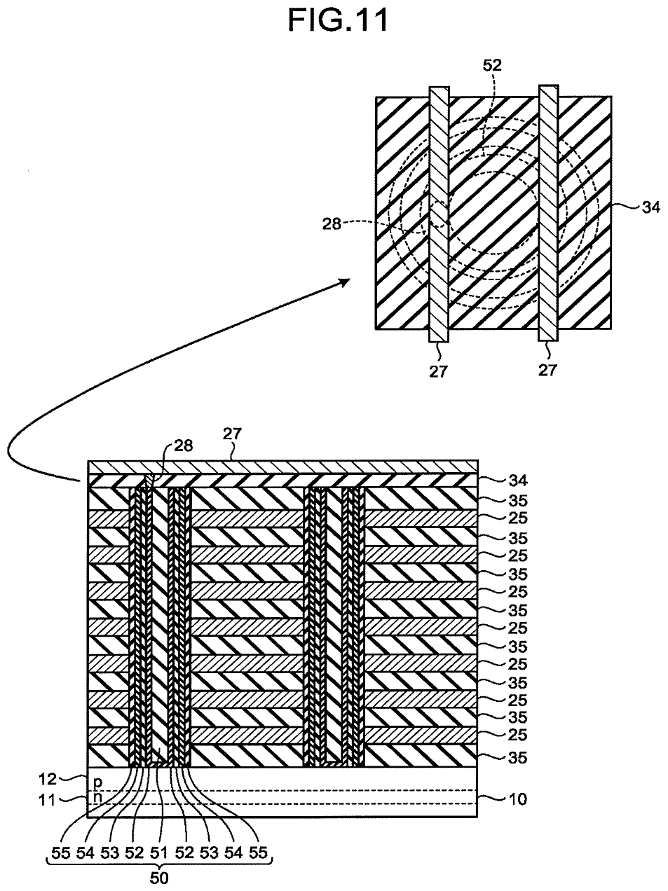

Then, as illustrated in FIG. 11, the conductive layers 27 are formed on the insulating layer 34 such that each of the conductive layers 27 is at a position overlapping with a predetermined contact 28. Consequently, each conductive layer 27 is connected to the channel layer 52 of a predetermined columnar structure 50 through the corresponding contact 28.

As a result, the semiconductor memory device 1 according to the embodiment is manufactured.

As described above, the channel layer to be shared by memory cells is formed by, for example, deposition into the corresponding memory hole. Accordingly, the channel layer becomes a poor quality layer, which is mainly made of amorphous silicon, polysilicon, or the like, and thus contains crystal defects. In memory cells including such a channel layer, there is a case where the writing characteristic is deteriorated, for example, such that a steep distribution of threshold voltage Vth can be hardly obtained because adjacent memory cells mutually affect the threshold voltages Vth of their own in a writing operation.

In the semiconductor memory device 1 according to the embodiment, the channel layer 52 includes a layer that contains much single crystal silicon or polysilicon and has a low electrical resistivity. Consequently, the channel layer 52 is improved in mobility of electrons serving as carriers. Further, in the channel layer 52, the layer lower in electrical resistivity is formed on the core portion 51 side. Consequently, electrons are caused to flow in the channel layer 52 at a position distant from the interface with the tunnel insulating layer 53 and near the core portion 51, while avoiding crystal defects or the like that can be easily generated near the interface with the tunnel insulating layer 53. Thus, electrons can be less scattered or trapped by crystal defects. As a result, it is possible to obtain a steep distribution of threshold voltage Vth in each memory cell MC, and thereby to improve the writing characteristic.

In the semiconductor memory device 1 according to the embodiment, the channel layer 52 including the layer lower in electrical resistivity is formed by annealing at a relatively low temperature of 1,000° C. or lower. Consequently, it is possible to suppress the influence of thermal history in the manufacturing process for the semiconductor memory device 1. For example, annealing at a high temperature can affect the distribution of threshold voltage Vth by denaturing SiN or the like forming the charge accumulation layer 54. On the other hand, annealing at a low temperature can suppress such an influence. Further, for example, in the case of annealing at a high temperature after formation of the conductive layers to be word lines, there is a concern that corrosive degassing is caused from the conductive layers. On the other hand, the semiconductor memory device 1 according to the embodiment does not entail such a concern.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked body in which a plurality of insulating layers and a plurality of conductive layers are alternately stacked above a substrate;
a pillar that penetrates the stacked body while extending in a stacking direction of the stacked body; and
a semiconductor layer, a first insulating layer, a charge accumulation layer, and a second insulating layer, which are stacked on a side surface of the pillar in order from the pillar,
wherein the semiconductor layer has an average grain size that is larger on a side nearer to the pillar and is smaller on a side nearer to the first insulating layer.

2. The semiconductor memory device according to claim 1, wherein the semiconductor layer has crystallinity that is higher on a side nearer to the pillar and is lower on a side nearer to the first insulating layer.

3. The semiconductor memory device according to claim 1, wherein the semiconductor layer contains single crystal silicon or polysilicon on a side nearer to the pillar and contains amorphous silicon on a side nearer to the first insulating layer.

4. The semiconductor memory device according to claim 1, wherein the semiconductor layer contains single crystal silicon on a side nearer to the pillar and contains amorphous silicon or polysilicon on a side nearer to the first insulating layer.

5. The semiconductor memory device according to claim 1, wherein the semiconductor layer contains single crystal silicon on a side nearer to the pillar and contains amorphous silicon on a side nearer to the first insulating layer.

6. The semiconductor memory device according to claim 1, wherein the semiconductor layer contains single crystal silicon on a side nearer to the pillar and contains polysilicon on a side nearer to the first insulating layer.

7. The semiconductor memory device according to claim 1, wherein the semiconductor layer contains polysilicon on a side nearer to the pillar and contains amorphous silicon on a side nearer to the first insulating layer.

8. The semiconductor memory device according to claim 1, wherein a part of the semiconductor layer, which is larger in the average grain size, has a thickness of 40% or more and 90% or less with respect to an entire thickness of the semiconductor layer.

9. The semiconductor memory device according to claim 1, wherein a part of the semiconductor layer, which is larger in the average grain size, has a thickness of 50% or more and 80% or less with respect to an entire thickness of the semiconductor layer.

10. The semiconductor memory device according to claim 1, wherein the semiconductor layer functions as a retrograde channel layer.

11. The semiconductor memory device according to claim 1, wherein the semiconductor layer is a silicon layer deposited in a hole that penetrates the stacked body.

12. The semiconductor memory device according to claim 11, wherein the semiconductor layer is a silicon layer annealed in a hydrogen atmosphere after deposition in the hole.

13. The semiconductor memory device according to claim 11, wherein the semiconductor layer is a silicon layer annealed at a temperature of 1,000° C. or lower in a hydrogen atmosphere after deposition in the hole.

14. The semiconductor memory device according to claim 11, wherein the pillar is an insulator filled in the hole formed with the semiconductor layer.

15. A semiconductor memory device comprising:
a pillar extending above a substrate in a direction intersecting with a main surface of the substrate; and
a plurality of memory cells arrayed on a side surface of the pillar, in a height direction of the pillar,
wherein
the memory cells include a channel layer covering a side surface of the pillar, and
the channel layer has an average grain size that is larger on a side nearer to the pillar and is smaller on a side opposite to the pillar.

16. The semiconductor memory device according to claim 15, wherein the channel layer contains single crystal silicon or polysilicon on a side nearer to the pillar and contains amorphous silicon on a side opposite to the pillar.

17. The semiconductor memory device according to claim 15, wherein the channel layer contains single crystal silicon on a side nearer to the pillar and contains amorphous silicon or poly icon on a side opposite to the pillar.

18. The semiconductor memory device according to claim 15, wherein a part of the channel layer, which is larger in the average grain size, has a thickness of 40% or more and 90% or less with respect to an entire thickness of the channel layer.

19. The semiconductor memory device according to claim 15, wherein the channel layer is a silicon layer that has been deposited in a hole to be filled with the pillar before formation of the pillar and then been annealed in a hydrogen atmosphere.

20. The semiconductor memory device according to claim 15, wherein the plurality of memory cells are nonvolatile memory cells respectively, and are electrically connected to each other in series to form a memory string.
